(19) United States
(12) Patent Application Publication
(10) Pub. No.: US 2010/0059097 A1
(43) Pub. Date: Mar. 11, 2010

(54) BIFACIAL MULTIJUNCTION SOLAR CELL

(76) Inventors: Mark McDonald, Milpitas, CA (US); Michael Ludowise, San Jose, CA (US)

Correspondence Address: BUCKLEY, MASCHOFF & TALWALKAR LLC, 50 LOCUST AVENUE, NEW CANAAN, CT, 06840, US

(21) Appl. No.: 12/206,045

(22) Filed: Sep. 8, 2008

(51) Int. Cl. H01L 31/042

(52) U.S. Cl. 136/244

(57) ABSTRACT

A device and a method for its fabrication. The device may include a first at least partially transparent surface, a second at least partially transparent surface, a first photovoltaic cell between the first surface and the second surface and comprising a first photovoltaic material including a first p-n junction, a second photovoltaic cell between the first surface and the second surface and comprising a second photovoltaic material including a second p-n junction, and a third photovoltaic cell between the first surface and the second surface and comprising a third photovoltaic material including a third p-n junction a third p-n junction. A first bandgap associated with the first photovoltaic material is greater than a second bandgap associated with the second photovoltaic material, and a third bandgap associated with the third photovoltaic material is greater than the second bandgap associated with the second photovoltaic material.

### BACKGROUND

1. Field

Some embodiments generally relate to the conversion of sunlight to electric current. More specifically, embodiments may relate to improved photovoltaic cells for use in conjunction with solar collectors.

2. Brief Description

A solar cell includes photovoltaic material for generating charge carriers (i.e., holes and electrons) in response to received photons. The photovoltaic material includes a p-n junction which creates an electric field within the photovoltaic material. The electric field directs the generated charge through the photovoltaic material and to elements electrically coupled thereto. Many types of solar cells are known, which may differ from one another in terms of constituent materials, structure and/or fabrication methods. A solar cell may be selected for a particular application based on its efficiency, electrical characteristics, physical characteristics and/or cost.

Multijunction solar cells generally include two or more monojunction solar cells (i.e., a cell as described above) stacked on one another. The photovoltaic material of each of the monojunction solar cells is associated with a different bandgap. Each monojunction solar cell of the multijunction solar cell absorbs (i.e., converts) photons from different portions of the solar spectrum. Accordingly, a multijunction solar cell provides improved photon conversion efficiency as compared to any one of its constituent monojunction solar cells. Due to production and material costs, however, multijunction cells are currently cost-effective only in niche applications (e.g., extra-terrestrial power generation).

A multijunction solar cell employing three monojunction solar cells is referred to as a triple-junction solar cell. Existing approaches to improving these triple-junction solar cells are limited to seeking greater performance at constant cost, lower cost at constant performance, or any beneficial compromise of increased performance at increased cost. The opportunities for performance improvement at constant cost are limited, as is the potential for cost reduction at constant performance.

Increased performance at increased cost may be attained by adding at least one monojunction cell to the conventional triple-junction cell. Such a quadruple-junction cell entails increases in processing and material costs. However, any increased performance is dependent upon the spectral conditions in which such a cell is deployed. Accordingly, the increase in performance may not justify the increased costs.

It has been proposed to employ multijunction solar cells in conjunction with concentrating solar radiation collectors. Concentrating solar radiation collectors may increase the output of any solar cell for a given amount of semiconductor material. Generally, a concentrating solar radiation collector receives solar radiation (i.e., sunlight) over a first surface area and directs the received sunlight to an active area of a solar cell. The active area of the solar cell is several times smaller than the first surface area, yet receives substantially all of the photons received by first surface area. The solar cell may thereby provide an electrical output equivalent to that of a solar cell which receives non-concentrated sunlight onto an active area the size of the first surface area.

Reducing a size of the solar cell for a constant input surface area will increase the concentration and the resulting cell efficiency. This approach requires tighter solar tracking, which also introduces additional costs that may outweigh the efficiency benefits.

### BRIEF DESCRIPTION OF THE DRAWINGS

The construction and usage of embodiments will become readily apparent from consideration of the following specification as illustrated in the accompanying drawings, in which like reference numerals designate like parts.

FIG. 1 is a cutaway plan view of a device according to some embodiments.

FIG. 2 is a cutaway plan view of a device according to some embodiments.

FIG. 3A illustrates operation of a conventional concentrating solar collector system.

FIG. 3B illustrates operation of a concentrating solar collector system according to some embodiments.

FIG. 3C illustrates operation of a concentrating solar collector system according to some embodiments.

FIG. 4 is a cutaway plan view of a device according to some embodiments.

FIG. 5 is a cutaway plan view of a device according to some embodiments.

FIG. 6 illustrates fabrication of two devices according to some embodiments.

### DETAILED DESCRIPTION

The following description is provided to enable any person in the art to make and use the described embodiments and sets forth the best mode contemplated by for carrying out some embodiments. Various modifications, however, will remain readily apparent to those in the art.

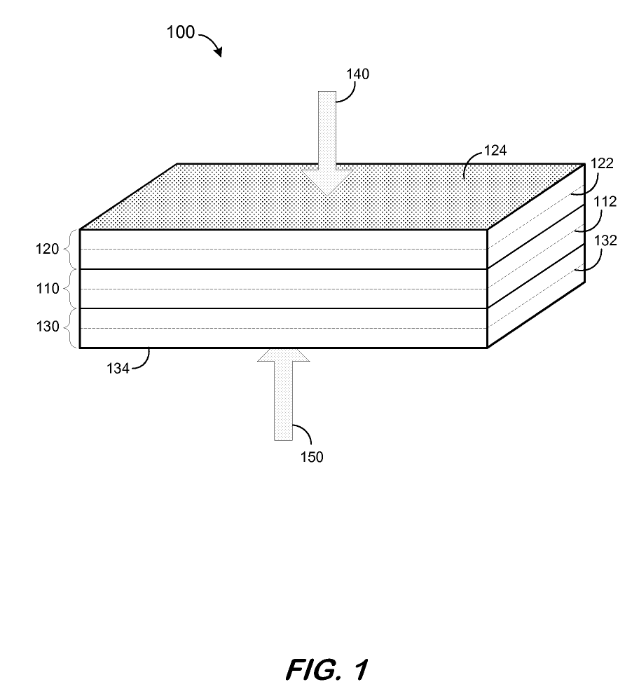

Device 100 of FIG. 1 is a bifacial multijunction photovoltaic cell according to some embodiments. Device 100 includes photovoltaic cell 110 composed of a first photovoltaic material, photovoltaic cell 120 composed of a second photovoltaic material, and photovoltaic cell 130 composed of a third photovoltaic material. Each of cells 110 through 130 includes a respective p-n junction, specifically p-n junction 112 within photovoltaic cell 110, p-n junction 122 within photovoltaic cell 120, and p-n junction 132 within photovoltaic cell 130.

First surface 124 and second surface 134 are disposed on opposite sides of device 100. P-n junctions 112, 122, and 132 are disposed between first surface 124 and second surface 134. First surface 124 and second surface 134 are at least partially transparent. In this regard, photons of at least part of the sunlight spectrum may pass through first surface 124 and second surface 134 during operation of device 100.

Each of the first, second and third photoconductive materials is associated with a bandgap. The bandgap is an energy difference between the top of a material's valence band and the bottom of its conduction band. A first bandgap associated with the first photovoltaic material of first photovoltaic cell 110 is less than a second bandgap associated with the second photovoltaic material of second photovoltaic cell 120, and the first bandgap is also less than a third bandgap associated with the third photovoltaic material of third photovoltaic cell 130.

Surface 124 may receive light 140 having any suitable intensity or spectra. Some photons of light 140 are absorbed by second photovoltaic cell 120. More particularly, photons of light 140 which exhibit energies greater than the second bandgap enter second photovoltaic cell 120 and liberate holes in an n-region (uppermost in FIG. 1) and electrons in a p-region (next uppermost in FIG. 1) of second photovoltaic cell 120. The liberated electrons may be pulled into the n-region and the liberated holes may be pulled into the p-region by means of an electric field established by and along p-n junction 122.

Photons of light 140 which exhibit energies less than the second bandgap may pass through second photovoltaic cell 120 and into first photovoltaic cell 110. Any of such photons which exhibit energies greater than the first bandgap may liberate electrons in the p-region and holes in the n-region of first photovoltaic cell 110. Again, the liberated electrons may be pulled into the n-region and the liberated holes may be pulled into the p-region of photovoltaic cell 110 by means of an electric field established by and along p-n junction 112.

A similar process may occur with respect to light 150 received by surface 134. Specifically, photons of light 150 which exhibit energies greater than the third bandgap of third photovoltaic cell 130 enter third photovoltaic cell 130 and liberate holes in an n-region and electrons in a p-region. The liberated electrons may be pulled into the n-region and the liberated holes may be pulled into the p-region of third photovoltaic cell 130 by means of an electric field established by and along p-n junction 132.

Photons of light 140 which exhibit energies less than the third bandgap may pass through third photovoltaic cell 130 and into a p-region of photovoltaic cell 110. Any of such photons which exhibit energies greater than the first bandgap may liberate holes in the n-region and electrons in the p-region. The liberated electrons and holes may be pulled into the n-region of photovoltaic cell 110, respectively, by means of the electric field along p-n junction 112.

The foregoing structure provides a bifacial multijunction solar cell according to some embodiments. Any suitable materials that are or become known may be incorporated into device 100. For example, each of the first through third photovoltaic materials may comprise elements from Group IV, or paired elements from Groups II-VI or from Groups II-V of the periodic table. According to some embodiments, the first photovoltaic material comprises Ge, and the second and third photovoltaic materials comprise GaAs. In this regard, the second bandgap and the third bandgap may be substantially equal, but embodiments are not limited thereto.

Device 100 may include unshown active, dielectric, metallization and other layers and/or components that are or become known, and may be fabricated using any suitable methods that are or become known. According to conventional multijunction solar cell design, a first tunnel diode layer may be disposed between photovoltaic cell 120 and 110, and a second tunnel diode layer may be disposed between photovoltaic cell 110 and 130. Device 100 may also include electrical contacts for extracting electrical current generated by device 100. Each of photovoltaic cells 110 through 130 may include several layers of various photovoltaic compositions and dopings.

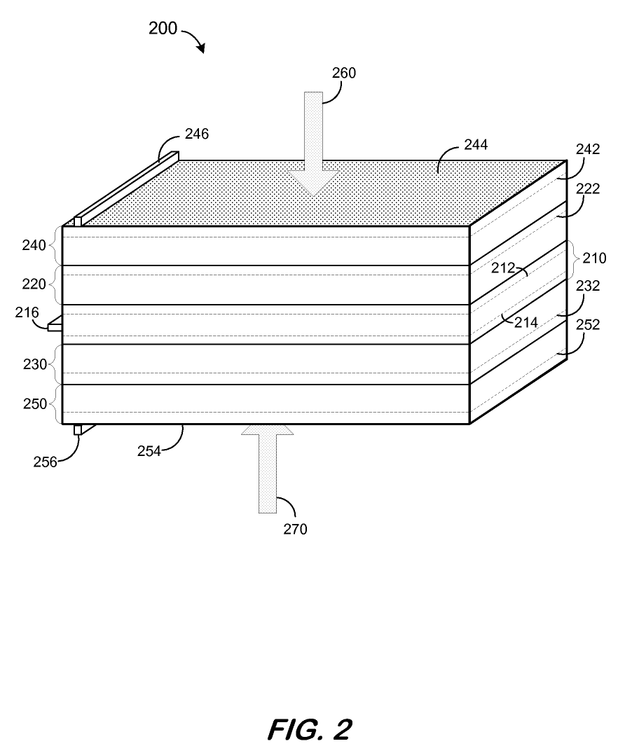

FIG. 2 is a cutaway plan view of device 200 according to some embodiments. Device 200 includes photovoltaic cells 210 through 250 composed of respective photovoltaic materials. Photovoltaic cell 210 includes p-n junctions 212 and 224, while each of photovoltaic cells 220 through 250 includes one of respective p-n junctions 222 through 252.

First surface 244 and second surface 254 are disposed on opposite sides of device 200. First surface 244 is at least partially transparent to sunlight 260 and second surface 254 is at least partially transparent to sunlight 270. As illustrated, p-n junctions 212 through 252 are positioned such that the narrower n-region of a photovoltaic cell receives incoming photons before its respective (and larger) p-region.

A bandgap of photovoltaic cell 250 is greater than a bandgap of photovoltaic cell 230, which is in turn greater than a bandgap of photovoltaic cell 210. Similarly, a bandgap of photovoltaic cell 240 is greater than a bandgap of photovoltaic cell 220, which is in turn greater than a bandgap of photovoltaic cell 210. The foregoing structure allows photovoltaic cell 250 (or 240) to absorb photons of a certain energy spectra and to pass photons having lesser energies to photoconductive cell 230 (220), which absorbs photons of a lesser energy spectra and passes photons having even lesser energies to photoconductive cell 210 for absorption.

Common conductive contact 216 is electrically coupled to photovoltaic cell 210, and negative conductive contacts 246 and 256 are coupled to photovoltaic cell 240 and to photovoltaic cell 250, respectively. The conductive contacts may be coupled to external circuitry to provide electrical current generated by device 200 thereto. Specifically, contacts 246 and 256 collect electrons generated by device 200 and contact 216 provides a return path.

Embodiments are not limited to the depicted contact structure. For example, contacts 246 and 256 may be disposed over surface areas 244 and 254, respectively, in a grid-like pattern to facilitate suitable collection of the generated electrons.

Photovoltaic cell 210 may comprise Ge, GaAs, Si, or any other suitable substrate. Some examples of photovoltaic cells 220 and 230 include GaAs and GaInP, while examples of photovoltaic cells 240 and 250 include AlInP, GaInP and AlGaInP. According to some embodiments, the photovoltaic material of photovoltaic cell 220 is identical to the photovoltaic material of photovoltaic cell 230, and the photovoltaic material of photovoltaic cell 240 is identical to the photovoltaic material of photovoltaic cell 250.

Various layers of device 200 may be formed using molecular beam epitaxy and/or metal organic chemical vapor deposition. According to some embodiments, photovoltaic cell 210 is fabricated according to known techniques and the remaining photovoltaic cells are deposited thereon. For example, photovoltaic cell 220 may be grown on photovoltaic cell 210, followed by growth of photovoltaic cell 240 on photovoltaic cell 220. Next, photovoltaic cell 230 may be grown on photovoltaic cell 210, followed by growth of photovoltaic cell 250 on photovoltaic cell 230. Alternatively, photovoltaic cells 220 and 230 may be grown simultaneously on opposite sides of photovoltaic cell 210, followed by simultaneous growth of photovoltaic cells 240 and 250 on photovoltaic cells 220 and 230, respectively.

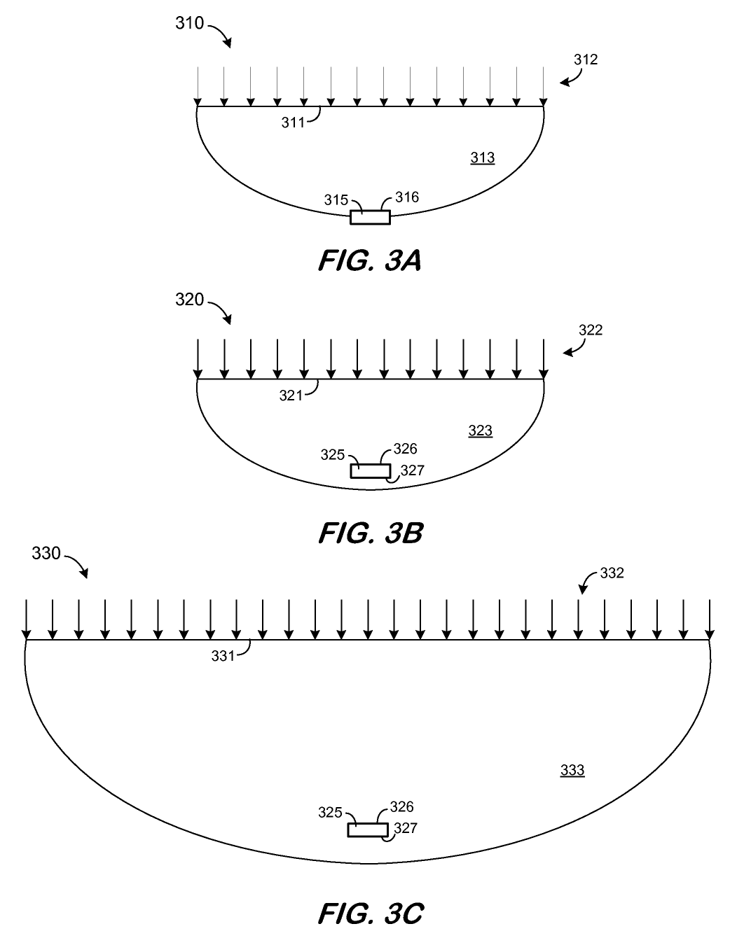

FIG. 3A illustrates operation of a conventional concentrating solar collector. Solar collector 310 includes monofacial solar cell 315. Monofacial solar cell 315 is fabricated on a semiconductor substrate and includes area 316 for receiving photons. It will be assumed that monofacial solar cell 315 is a multifunction cell including photovoltaic cells 210, 220 and 240 of FIG. 2.

In operation, entrance area 311 of solar collector 310 receives sunlight 312. Concentrator 313 includes any type, number and arrangement of optics to concentrate sunlight 312 and to direct a beam of concentrated sunlight onto surface area 316. Solar cell 315 then generates electrical current based on a number and intensity of the received photons and on its conversion (i.e., photon to electron conversion) efficiency.

FIG. 3B illustrates operation of concentrating solar collector 320 used in conjunction with bifacial multifunction solar cell 325 according to some embodiments. For comparative purposes, it will be assumed that bifacial multifunction solar cell 325 is physically identical to solar cell 315 but also includes cells 230 and 250 and conductive contacts as shown in FIG. 2. Surface 316 of solar cell 315 is identical in area to surface 326 of solar cell 325 and is also identical in area to surface 327 of solar cell 325.

A size of entrance area 321 is equal to a size of entrance area 311, and concentrator 323 concentrates light 322 to a same degree as concentrator 313 concentrates light 312. In the case of solar cell 325, concentrator 323 may direct half the concentrated light to surface 326 and half the concentrated light to surface 327.

By virtue of the foregoing, solar cell 325 and solar cell 315 receive concentrated light over a same amount of surface area and output similar levels of current. However, since the total active surface area of solar cell 325 is twice the active surface area of solar cell 315, solar collector 320 of an appropriate design will exhibit a significantly greater tolerance to tracking error than does solar collector 310.

FIG. 3C illustrates operation of a concentrating solar collector 330 is used in conjunction with bifacial multijunction solar cell 325 as described above. Entrance area 331 of solar collector 310 is twice the size of entrance area 311 of solar collector 330. Solar collector 330 receives sunlight 332 over entrance area 331 and concentrator 333 concentrates sunlight 332 to a same degree as concentrator 313 concentrates light 312.

Solar cell 325 receives the concentrated light at surfaces 326 and 327. Due to the doubling in size of entrance area 331 and the identical concentration provided by concentrator 333, the surface area of cell 325 over which light is received in FIG. 3C is double the surface area of cell 325 over which light is received in FIG. 3B. Solar cell 325 of FIG. 3C generates electrical current based on a number and intensity of the received photons and on its conversion efficiency.

In comparison to the operation depicted in FIG. 3A, solar cell 325 of FIG. 3C may receive and convert twice as many photons to electrical current for a same amount of substrate material. Moreover, since solar cell 325 of FIG. 3C and according to the FIG. 2 arrangement exhibits double the open-circuit voltage of solar cell 315, a conversion efficiency of solar cell 325 may be greater than a conversion efficiency of solar cell 315. The increased efficiency may result solar cell 325 generating more than double the electrical current of solar cell 315 for the same volume of semiconductor substrate.

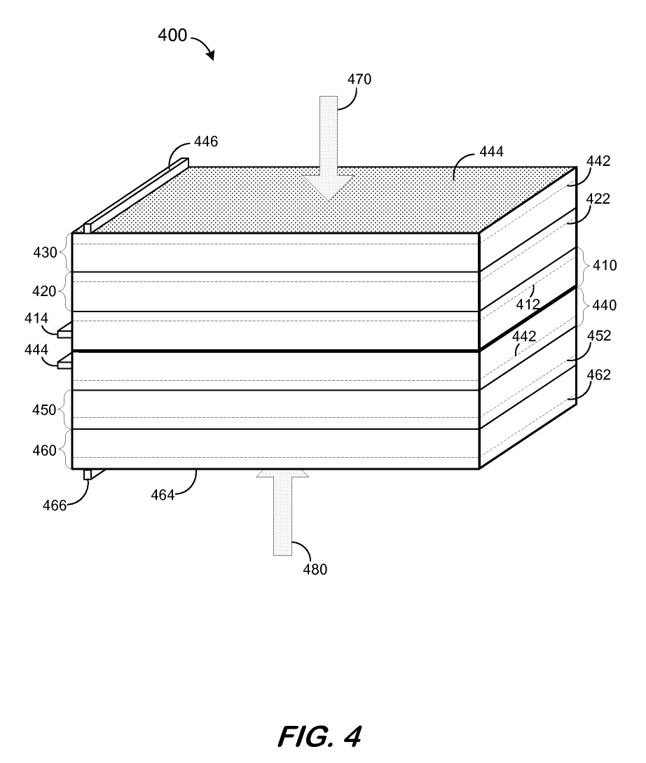

FIG. 4 is a cutaway plan view of device 400 according to some embodiments. Device 400 includes photovoltaic cells 410 through 460 composed of respective photovoltaic materials. Any descriptions provided herein of suitable materials, fabrication techniques and design alternatives also apply to device 400.

Photovoltaic cell 410 may comprise a substrate material (e.g., Ge) including p-n junction 412. Photovoltaic cells 420 and 430 include p-n junctions 422 and 442, and comprise photovoltaic material exhibiting increasingly larger bandgaps as described above.

Similarly, photovoltaic cell 440 may comprise a substrate material including p-n junction 442, and photovoltaic cells 450 and 460 include p-n junctions 452 and 462. The bandgaps of photovoltaic cells 440, 450 and 460 increase progressively toward surface 464. Using the mechanisms described above, light 480 received at surface 464 may be converted to electrical current by photovoltaic cells 440, 450 and 460. Light 470 received at surface 444, on the other hand, may be converted to electrical current by photovoltaic cells 410, 420 and 430.

Photovoltaic cells 410, 420 and 430 are electrically isolated from photovoltaic cells 440, 450 and 460. Positive conductive contact 414 is electrically coupled to photovoltaic cell 410, and negative conductive contact 446 is coupled to photovoltaic cell 430. Positive conductive contact 444 is electrically coupled to photovoltaic cell 440, and negative conductive contact 466 is coupled to photovoltaic cell 460. Accordingly, electrical current generated by photovoltaic cells 410, 420 and 430 is carried by conductive contacts 414 and 446, and electrical current generated by photovoltaic cells 440, 450 and 460 is carried by conductive contacts 444 and 466.

Device 400 may be characterized as two conventional monofacial cells having substrates bonded to one another. According to some embodiments, photovoltaic cell 410 is fabricated according to known techniques and photovoltaic cells 420 and 430 are grown thereon. Photovoltaic cell 440 is separately fabricated and photovoltaic cells 450 and 460 are grown thereon. Next, using conventional wafer bonding techniques, substrates 410 and 440 are bonded together.

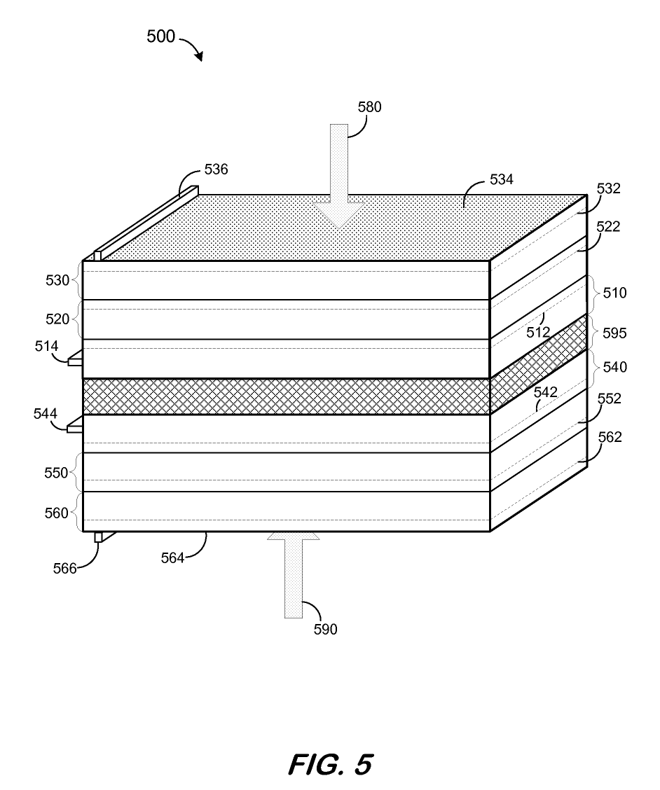

Device 500 of FIG. 5 may exhibit a construction similar to device 400. In this regard, the elements of FIG. 5 may be embodied as described above with respect to similarly-numbered elements of device 400. In contrast to device 400, device 500 includes non-semiconductor layer 595 disposed between photovoltaic cell 510 and photovoltaic cell 540. Each of photovoltaic cell stacks 510-530 and 540-560 may be individually fabricated and coupled to opposite sides of insulator layer 540.

Device 400 or device 500 may be employed as illustrated in FIG. 3B to provide increased tracking error tolerance for a given concentration. Device 400 or device 500 may be useful in systems for which the spatial uniformity in irradiance differs substantially for each optically-receptive surface area, and/or for which the generated current differs substantially for each electrically-independent portion.

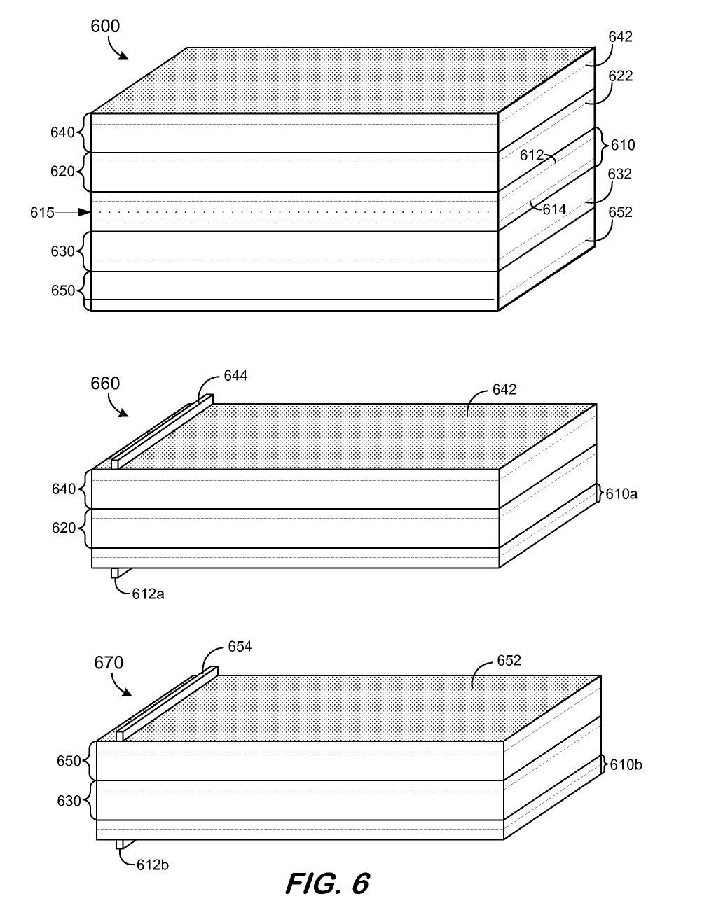

FIG. 6 is a cutaway plan view of bifacial multifunction device 600 according to some embodiments. The elements of device 600 may be embodied as described above with respect to similarly-numbered elements of device 200. Device 600 may be fabricated using any suitable techniques, including but not limited to those mentioned therein.

Photovoltaic cell 610 is a substrate including fracture plane 615. Fracture plane 615 may be created through wafer bonding techniques or by external action on an initially homogeneous wafer (e.g., ion implant, etc.). According to some embodiments, cell 610 is split along fracture plane 615 to generate two monofacial multifunction cells 660 and 670. Cell 660 includes cells 620, 640 and portion 610a of original cell 610, while cell 670 includes cells 630, 650 and portion 610b of original cell 610. Conductive contacts may be coupled to each of cells 660 and 670 to facilitate operation as described above.

The several embodiments described herein are solely for the purpose of illustration. Embodiments may include any currently or hereafter-known versions of the elements described herein. Therefore, persons skilled in the art will recognize from this description that other embodiments may be practiced with various modifications and alterations.

What is claimed is:

1. A device comprising:
a first surface, the first surface at least partially transparent;
a second surface, the second surface at least partially transparent;
a first photovoltaic cell between the first surface and the second surface and comprising a first photovoltaic material including a first p-n junction;
a second photovoltaic cell between the first surface and the second surface and comprising a second photovoltaic material including a second p-n junction; and
a third photovoltaic cell between the first surface and the second surface and comprising a third photovoltaic material including a third p-n junction a third p-n junction,
wherein a first bandgap associated with the first photovoltaic material is greater than a second bandgap associated with the second photovoltaic material, and
wherein a third bandgap associated with the third photovoltaic material is greater than the second bandgap associated with the second photovoltaic material.

2. A device according to claim 1, wherein the second photovoltaic cell comprises a fourth p-n junction between the second p-n junction and the third p-n junction.

3. A device according to claim 2, further comprising:
a common conductive contact coupled to a p-doped region of the second photovoltaic cell;
a first negative conductive contact coupled to an n-doped region of the first photovoltaic cell; and
a second negative conductive contact coupled to an n-doped region of the third photovoltaic cell.

4. A device according to claim 1, wherein the first photovoltaic material and the third photovoltaic material are substantially identical.

5. A device according to claim 1, further comprising:
a fourth photovoltaic cell between the first photovoltaic cell and the first surface, the fourth photovoltaic cell comprising a fourth photovoltaic material and including a fourth p-n junction;
a fifth photovoltaic cell between the third photovoltaic cell and the second surface, the fifth photovoltaic cell comprising a fifth photovoltaic material and including a fifth p-n junction,
wherein a fourth bandgap associated with the fourth photovoltaic material is greater than a first bandgap associated with the first photovoltaic material, and
wherein a fifth bandgap associated with the fifth photovoltaic material is greater than the third bandgap associated with the third photovoltaic material.

6. A device according to claim 5,
wherein the first photovoltaic material and the third photovoltaic material are substantially identical, and
wherein the fourth photovoltaic material and the fifth photovoltaic material are substantially identical.

7. A device according to claim 1, further comprising:
a fourth photovoltaic cell between the second photovoltaic cell and the third photovoltaic cell, the fourth photovoltaic cell comprising a fourth photovoltaic material and including a fourth p-n junction,
wherein a fourth bandgap associated with the fourth photovoltaic material is less than the third bandgap associated with the third photovoltaic material.

8. A device according to claim 7, further comprising:
an electrical insulator layer disposed between the second photovoltaic cell and the fourth photovoltaic cell, the electrical insulator layer to electrically isolate the second photovoltaic cell from the fourth photovoltaic cell.

9. A device according to claim 7, further comprising:
a fifth photovoltaic cell between the first surface and the first photovoltaic cell, the fifth photovoltaic cell comprising a fifth photovoltaic material and including a fifth p-n junction; and
a sixth photovoltaic cell between the second surface and the third photovoltaic cell, the sixth photovoltaic cell comprising a sixth photovoltaic material and including a sixth p-n junction,
wherein a fifth bandgap associated with the fifth photovoltaic material is greater than the first bandgap associated with the first photovoltaic material, and
wherein a sixth bandgap associated with the sixth photovoltaic material is greater than the third bandgap associated with the third photovoltaic material.

10. A device according to claim 9, further comprising:
a first positive conductive contact coupled to a p-doped region of the second photovoltaic cell;
a second positive conductive contact coupled to a p-doped region of the fourth photovoltaic cell;
a first negative conductive contact coupled to an n-doped region of the fifth photovoltaic cell; and
a second negative conductive contact coupled to an n-doped region of the sixth photovoltaic cell.

11. A method comprising:
fabricating a first photovoltaic cell comprising a first photovoltaic material including a first p-n junction;
fabricating a second photovoltaic cell physically coupled to a first side of the first photovoltaic cell, the second photovoltaic cell comprising a second photovoltaic material including a second p-n junction;
fabricating a third photovoltaic cell physically coupled to a second side of the first photovoltaic cell, the third photovoltaic cell comprising a third photovoltaic material including a third p-n junction,
wherein a first bandgap associated with the first photovoltaic material is less than a second bandgap associated with the second photovoltaic material, and
wherein a first bandgap associated with the first photovoltaic material is less than a third bandgap associated with the third photovoltaic material.

12. A method according to claim 11, wherein fabricating the first photovoltaic cell comprises:
fabricating a fourth p-n junction, and
wherein the fourth p-n junction is between the third photovoltaic cell and the first p-n junction.

13. A method according to claim 12, further comprising:
fabricating a common conductive contact coupled to a p-doped region of the first photovoltaic cell.

14. A method comprising:
fabricating a first photovoltaic cell comprising a first photovoltaic material including a first p-n junction;
fabricating a second photovoltaic cell physically coupled to a first side of the first photovoltaic cell, the second photovoltaic cell comprising a second photovoltaic material including a second p-n junction;
fabricating a third photovoltaic cell comprising a third photovoltaic material including a third p-n junction;
fabricating a fourth photovoltaic cell physically coupled to a first side of the third photovoltaic cell, the fourth photovoltaic cell comprising a fourth photovoltaic material including a third p-n junction; and
coupling a second side of the first photovoltaic cell to a second side of the third photovoltaic cell,
wherein a first bandgap associated with the first photovoltaic material is less than a second bandgap associated with the second photovoltaic material, and
wherein a third bandgap associated with the third photovoltaic material is less than a fourth bandgap associated with the fourth photovoltaic material.

15. A method according to claim 14, wherein coupling the second side of the first photovoltaic cell to the second side of the third photovoltaic cell comprises:
coupling the second side of the first photovoltaic cell to an electrical insulator layer; and
coupling the second side of the third photovoltaic cell to the electrical insulator layer,
wherein the electrical insulator layer is to electrically isolate the first photovoltaic cell from the third photovoltaic cell.

16. A method according to claim 14, further comprising:
fabricating a first positive conductive contact coupled to a p-doped region of the first photovoltaic cell; and
fabricating a second positive conductive contact coupled to a p-doped region of the third photovoltaic cell.
